(19) United States
(12) Patent Application Publication
(10) Pub. No.: US 2019/0164875 A1
(43) Pub. Date: May 30, 2019

(54) PREMOLDED SUBSTRATE FOR MOUNTING A SEMICONDUCTOR DIE AND A METHOD OF FABRICATION THEREOF

(71) Applicant: ASM Technology Singapore Pte Ltd, Singapore (SG)

(72) Inventor: Chun Ho FAN, Hong Kong (HK)

(21) Appl. No.: 15/822,697

(22) Filed: Nov. 27, 2017

(51) Int. Cl. H01L 23/498; H01L 23/28; H01L 21/768; H01L 21/48

(52) U.S. Cl. CPC H01L 23/49816; H01L 23/28; H01L 2021/60135; H01L 21/4853; H01L 21/76882

(57) ABSTRACT

A method of forming a premolded substrate for mounting a semiconductor die, comprising the steps of providing a carrier; forming conductive circuits on the carrier and forming a plurality of metallic contacts on the conductive circuits. Thereafter, the method further comprises encapsulating the carrier by compressing a top portion of each metallic contact to crush and flatten the top portion of each metallic contact, and introducing a molding compound to surround the plurality of metallic contacts such that the flattened top surfaces of the plurality of metallic contacts are exposed on and flush with a top surface of the molding compound.

### FIELD OF THE INVENTION

This invention relates to a semiconductor substrate and a method of fabricating the semiconductor substrate. In particular, it relates to a semiconductor substrate that is pre-molded for supporting semiconductor dice during semiconductor packaging.

### BACKGROUND

A semiconductor packaging process typically comprises mounting a semiconductor die onto a substrate, and thereafter encapsulating the semiconductor die in a molding compound, thus forming a semiconductor package. The substrate comprises electrical interconnections that functionally and electrically connect electrical contacts of the mounted semiconductor die to external electrical circuitry, and the molding compound protects the substrate and the semiconductor die mounted on it.

Traditionally, lead frames made of copper alloy or stainless steel are used as substrates to support semiconductor dice and to provide electrical interconnections. However, the strong demand for higher performance devices having smaller and thinner package sizes but higher lead counts has resulted in a rapid increase in the use of laminate substrates such as Ball-Grid Array (“BGA”) packages, molded interconnect substrates (“MIS”) and embedded trace substrates (“ETS”).

ETS uses a via to connect a top metallic layer to a bottom BGA layer. The manufacture of ETS comprises laser drilling the via in a dielectric material, followed by forming a seed metallic layer which is patterned for making electrical interconnections. However, laser drilling is an expensive and slow process, thus making ETS a relatively expensive substrate to manufacture and use.

MIS uses copper studs to connect a top metallic layer to a bottom BGA layer. In addition to forming the copper studs, the manufacture of MIS comprises additional processing steps such as grinding a dielectric layer to reveal the copper studs, and thereafter forming a patterned seed layer to form the bottom BGA layer. However, such MIS manufacturing processes are complicated and expensive, thus making the manufacture of MIS complicated and expensive.

### SUMMARY OF THE INVENTION

It is thus an object of this invention to seek to provide a method of manufacturing a substrate that is less complicated and/or less expensive than the prior art.

According to a first aspect of the invention, there is provided a method of forming a premolded substrate for mounting a semiconductor die, comprising the steps of: providing a carrier; forming conductive circuits on the carrier; forming a plurality of metallic contacts on the conductive circuits; and thereafter, encapsulating the carrier by compressing a top portion of each metallic contact to crush and flatten the top portion of each metallic contact, and introducing a molding compound to surround the plurality of metallic contacts such that the flattened top surfaces of the plurality of metallic contacts are exposed on and flush with a top surface of the molding compound.

According to a second aspect of the invention, there is provided a premolded substrate for mounting a semiconductor die, the premolded substrate comprising: conductive circuits; a plurality of metallic contacts on the conductive circuits; and a molding compound surrounding the plurality of metallic contacts and exposing a top surface of the metallic contacts; wherein the top surfaces of the plurality of metallic contacts have been crushed and flattened to be flush with a top surface of the molding compound.

These and other features, aspects, and advantages will be better understood with regard to the description section, appended claims, and accompanying drawings.

### BRIEF DESCRIPTION OF THE DRAWINGS

Embodiments of the present invention will now be described, by way of example only, with reference to the accompanying drawings, in which:

FIG. 1 is a flowchart showing the steps in a manufacturing process for forming a pre-molded substrate according to a first preferred embodiment of the invention;

FIGS. 2A-2B respectively illustrate plan and cross-sectional views of a carrier;

FIGS. 3A-3B respectively illustrate plan and cross-sectional views of a metallic layer formed onto a first surface of the carrier;

FIGS. 4A-4B respectively illustrate plan and cross-sectional views of electrical contacts formed on the metallic layer;

FIGS. 5A-5B respectively illustrate plan and cross-sectional views of a metallic trace layer formed on the metallic layer and the electrical contacts;

FIGS. 6A-6B respectively illustrate plan and cross-sectional views of solder contact pads formed on the metallic trace layer at cylindrical portions corresponding to positions of BGA pads;

FIGS. 7A-7B respectively illustrate plan and cross-sectional views of the first surface of the carrier after an adhesion promotion treatment has been carried out;

FIGS. 8A-8B respectively illustrate plan and cross-sectional views of a respective metallic contact formed on each solder contact pad;

FIGS. 9A-9B respectively illustrate plan and cross-sectional views of the carrier encapsulated by a first encapsulant;

FIGS. 10A-10B respectively illustrate plan and cross-sectional views of the pre-molded substrate after the carrier and the metallic layer have been removed;

FIGS. 11A-11B respectively illustrate plan and cross-sectional views of the pre-molded substrate after an adhesion promotion treatment has been carried out on a second surface of the carrier;

FIGS. 12A-12B respectively illustrate plan and cross-sectional views of the pre-molded substrate that is formed;

FIGS. 13A-13B respectively illustrate plan and cross-sectional views of a semiconductor die attached to the pre-molded substrate via semiconductor die contacts;

FIGS. 14A-14B respectively illustrate plan and cross-sectional views of the attached semiconductor die encapsulated by a second encapsulant;

FIG. 15 is a flowchart showing the steps in another manufacturing process for forming a pre-molded substrate according to a second preferred embodiment of the invention;

FIGS. 16A-16B respectively illustrate plan and cross-sectional views of a carrier;

FIGS. 17A-17B respectively illustrate plan and cross-sectional views of a metallic layer formed onto a first surface of the carrier;

FIGS. 18A-18B respectively illustrate plan and cross-sectional views of metallic trace patterns formed on the carrier;

FIGS. 19A-19B respectively illustrate plan and cross-sectional views of a respective solder ball formed on each metallic trace pattern;

FIGS. 20A-20B respectively illustrate plan and cross-sectional views of the carrier encapsulated by an encapsulant; and

FIGS. 21A-21B respectively illustrate plan and cross-sectional views of the pre-molded substrate after the carrier and the adhesive have been removed.

In the drawings, like parts are denoted by like reference numerals.

### DETAILED DESCRIPTION OF THE PREFERRED EMBODIMENT OF THE INVENTION

In the Summary section, in the Description section, in the appended claims, and in the accompanying drawings, it will be appreciated that when a layer is referred to as being “on” another layer or substrate, it can be directly on the other layer or substrate, or intermediate layers may also be present. It should also be noted that certain aspects of the figures have been exaggerated for illustration purposes.

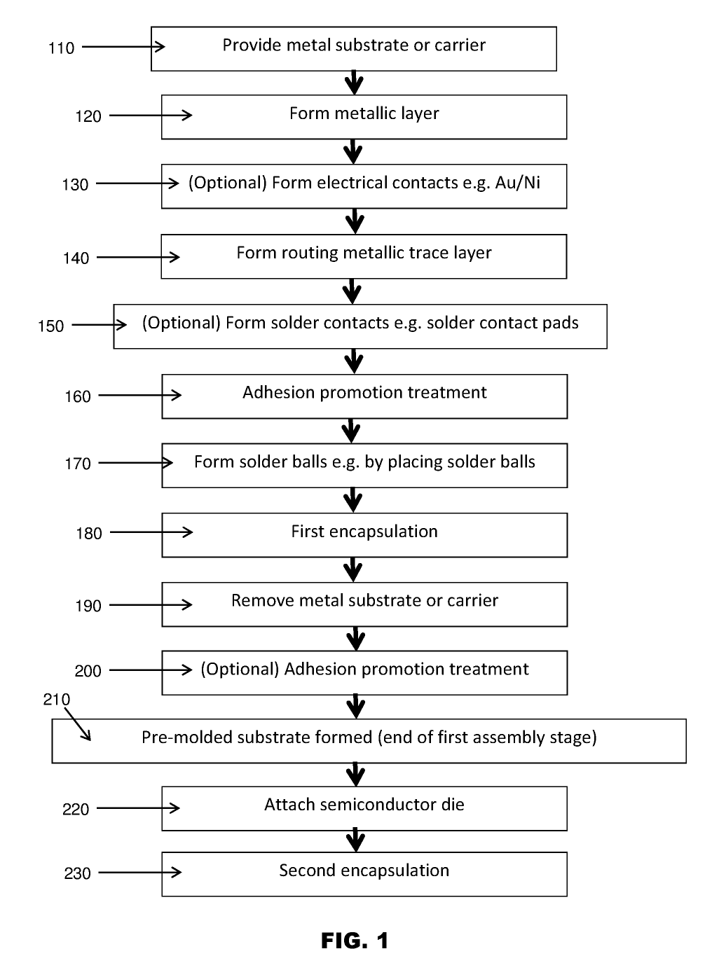

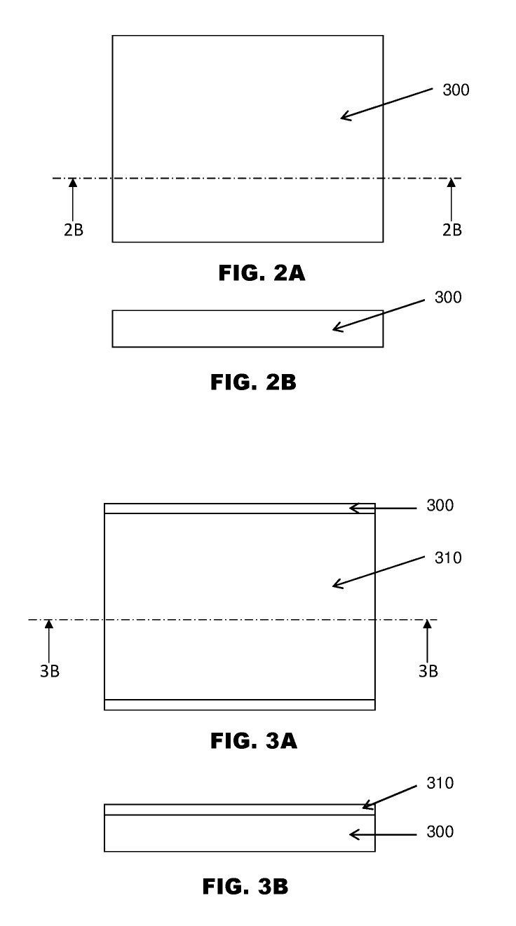

FIG. 1 is a flowchart showing the steps in a manufacturing process for forming a pre-molded substrate according to a first preferred embodiment of the invention, where FIGS. 2A through 14B illustrate plan and cross-sectional views of the pre-molded substrate at various stages of the manufacturing process of FIG. 1.

At step 110, a metal substrate or carrier 300 is provided. A plan view of a first surface of the carrier 300 is shown in FIG. 2A, and FIG. 2B shows a cross-sectional view of the carrier 300 looking along line 2B-2B in FIG. 2A. The carrier 300 may comprise iron and may act as a temporary carrier to be removed in a later processing step, which is described below.

At step 120, a metallic layer 310 is formed onto the first surface of the carrier 300, as shown in FIGS. 3A-3B. The metallic layer 310 may be a seed layer comprising copper. The thickness of the metallic layer 310 may be in the range of about 0.001 to 5 microns. The metallic layer 310 may be obtained by electrolytic plating or electroless plating, or by depositing a conductive material using physical or chemical deposition methods such as sputtering, thermal evaporation, or e-beam deposition. In addition, there are many other well-known plating or deposition processes in the art, and it is not intended that the present invention be limited to any particular plating or deposition process.

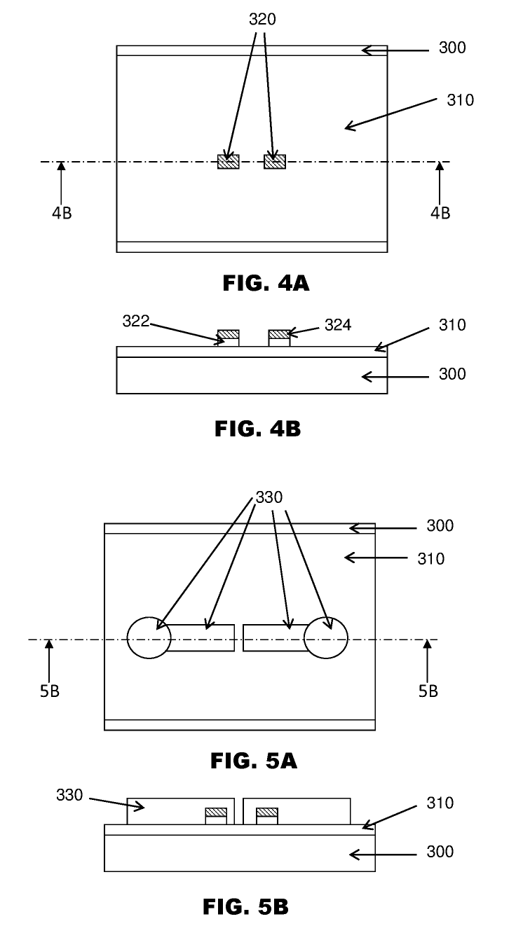

At optional step 130, electrical contacts 320, such as package level interconnect contacts, may be formed on the metallic layer 310, as shown in FIGS. 4A-4B. The electrical contacts 320 may each comprise a first contact metal 322 and a second contact metal 324. The electrical contacts 320 may be utilized for downstream wire bonding or flip chip bonding processes. The material used for the electrical contacts 320 would depend on the design specifications of the final electronic device, and may for example comprise gold, palladium or nickel. The electrical contacts 320 may be formed by any plating or deposition method, and it is not intended that the present invention be limited to any particular plating or deposition process.

At step 140, a metallic trace layer 330, such as a routing metal trace layer, is formed on the metallic layer 310 and the electrical contacts 320, as shown in FIGS. 5A-5B. The metallic trace layer 330 forms conductive circuits or electrical interconnections within the pre-molded substrate, where cylindrical portions of the metallic trace layer 330 correspond to the positions of the BGA pads of the final electronic device. The metallic trace layer 330 may for instance comprise copper.

The metallic trace layer 330 is connected to and entirely, or at least partially surrounds, the electrical contacts 320. The advantage of forming the electrical contacts 320 to be at least partially surrounded by the metallic trace layer 330, such as by embedding it within the metallic trace layer 330, is that different materials may be used for the metallic trace layer 330 and the electrical contacts 320, in order to suit the application or requirements of the final electronic device. For instance, the material chosen for the metallic trace layer 330 may be a material which is able to adhere well to a molding compound to be introduced in a subsequent processing step, and the material chosen for the electrical contacts 320 may be a different material which is able to bond well to a semiconductor die in another subsequent processing step.

The metallic trace layer 330 may be formed by applying a plating resist layer, such as a photoresist layer, onto the metallic layer 310, then masking, exposing, developing, and removing portions of the photoresist layer. Thereafter, a metallic trace layer 330 is plated or deposited over exposed areas of the photoresist layer. Subsequently, the remaining photoresist layer is removed, thus forming the metallic trace layer 330 as shown in FIGS. 5A-5B. There are many other well-known metallic layer forming processes in the art, and it is not intended that the present invention be limited to any particular metallic layer forming process.

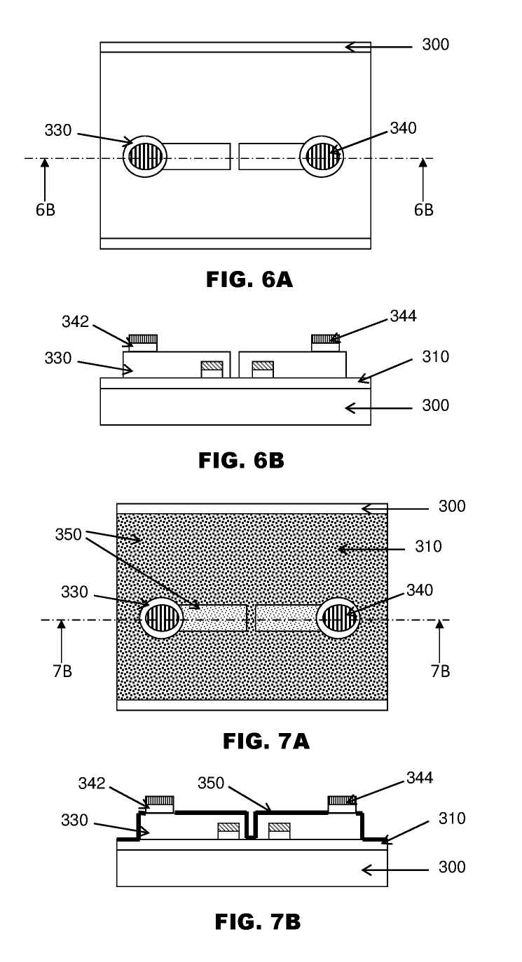

As an optional step 150, metallic contact pads or solder contact pads 340 may be formed on the metallic trace layer 330 at the cylindrical portions corresponding to the positions of the BGA pads, as shown in FIGS. 6A-6B. The solder contact pads 340 may each comprise a first solder contact metal 342 and a second solder contact metal 344. The material used for the solder contacts 340 would depend on the design specifications of the final electronic device, and may for example comprise gold or nickel. The solder contact pads 340 may be formed by any plating or deposition method, and it is not intended that the present invention be limited to any particular plating or deposition process.

At step 160, an adhesion promotion treatment may be carried out on the first surface of the carrier 300, as shown in FIGS. 7A-7B. The adhesion promotion treatment may be carried out on selected surfaces, such that exposed surfaces 350 of the metallic layers 310, 330 are roughened. The exposed surfaces 350 that have been treated help to promote adhesion between the exposed surfaces 350 and a molding compound to be introduced subsequently.

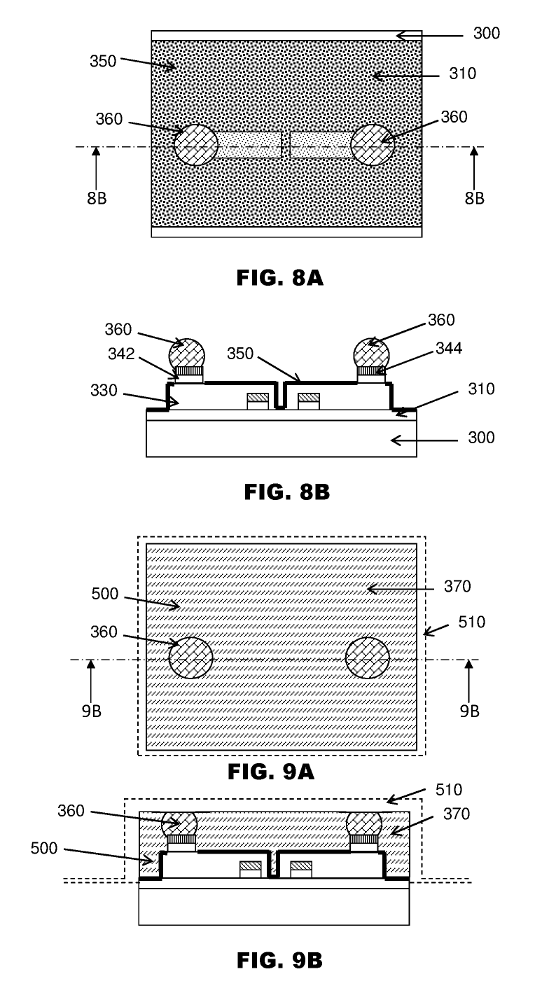

At step 170, a respective metallic contact, such as a solder contact or a solder ball 360, is formed on each solder contact pad 340 or each cylindrical portion of the metallic trace layer 330, as shown in FIGS. 8A-8B. The height and diameter of the solder balls 360 may vary widely, and is selected based on design specifications of the final electronic device. The solder balls 360 may be deposited by printing solder paste, and thereafter reflowing and cleaning, or by placing solder balls 360 directly onto the solder contact pads 340 with pre-deposited flux followed by reflowing and cleaning.

At step 180, the first surface of the carrier 300 is encapsulated by a first molding compound or a first encapsulant 370, as shown in FIGS. 9A-9B. The first encapsulant 370 covers the exposed surfaces 350 and leaves top surfaces of the solder balls 360 exposed on and flush with a top surface of the first encapsulant 370. The first encapsulant 370 allows the final electronic device to perform reliably in extreme operating temperature environments and to possess superior structural integrity.

The carrier 300 may be encapsulated in a molding system comprising a molding cavity 500 for holding the carrier 300, and a top mold plate 510 which is movable relative to a bottom mold plate of a molding machine. The carrier 300 may be held in the molding cavity 500 by being clamped between the top mold plate 510 and the bottom mold plate of the molding machine. While a molding compound is being introduced into the molding cavity 500, a surface of the top mold plate 510 may apply a compressive force onto the top surfaces of the solder balls 360 to deform or crush and flatten the top surfaces of the solder balls 360. Alternatively, a surface of the bottom mold plate may be used to apply the compressive force to crush or deform and flatten the top surfaces of the solder balls 360. The top mold plate 510 also shapes the molding compound in the molding cavity 500 into the desired shape and height. The molding compound embeds the routing metallic trace layer 330 and partially embeds the solder balls 360, flattening the top portions of the solder balls 360 and leaving the said top portions exposed on and flush with a top surface of the molding compound. The exposed portions of the solder balls may be used for broad level interconnections during broad level assembly.

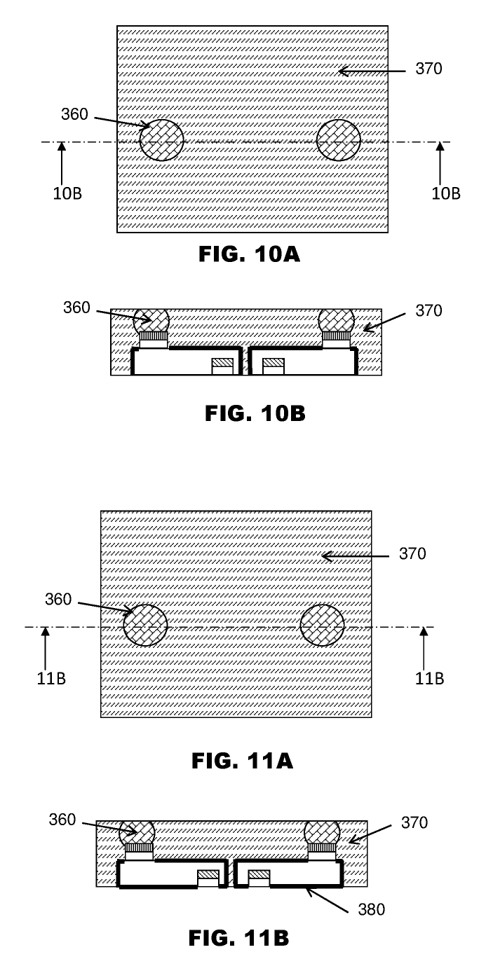

At step 190, the carrier 300 is removed along with the metallic layer 310, as shown in FIGS. 10A-10B. The carrier 300 and the metallic layer 310 may be removed by a dry etching method, a wet etching method such as chemical removal, or a combination of dry and wet etching methods. In addition, there are many other well-known etching processes and etchants in the art, and it is not intended that the present invention be limited to any particular etching or removal process. Generally, the carrier 300 and the metallic layer 310 is removed prior to mounting a semiconductor die 390 onto the premolded substrate.

At optional step 200, an adhesion promotion treatment may be carried out on a second surface of the pre-molded substrate, as shown in FIGS. 11A-11B. The adhesion promotion treatment may be carried out on selected surfaces, such that bottom exposed surfaces 380 of the metallic trace layer 330 are roughened. The bottom exposed surfaces 380 help to promote adhesion between the bottom exposed surfaces 380 and a molding compound to be introduced subsequently.

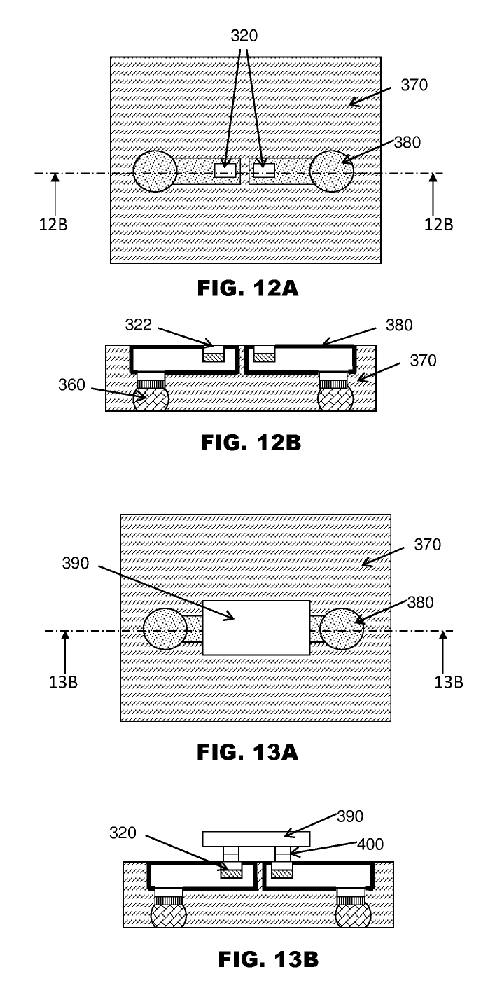

At step 210, the pre-molded substrate is formed, as shown in FIGS. 12A-12B. The pre-molded substrate has been flipped 180° such that the bottom exposed surfaces 380 of the metallic trace layer 330 and the electrical contacts 320 are facing upwards and the exposed top portions of the solder balls 360 are facing downwards. Step 210 is the last step of a first assembly stage of the semiconductor packaging process.

At step 220, a semiconductor die 390 is attached, for instance by a flip chip bonding process, to the pre-mold substrate via semiconductor die contacts 400, as shown in FIGS. 13A-13B. The semiconductor die 390 may be attached to the electrical contacts 320 by a flip chip bonding process wherein the semiconductor die 390 is placed onto the electrical contacts 320, and thereafter reflowed to form an electrically conductive bond therebetween.

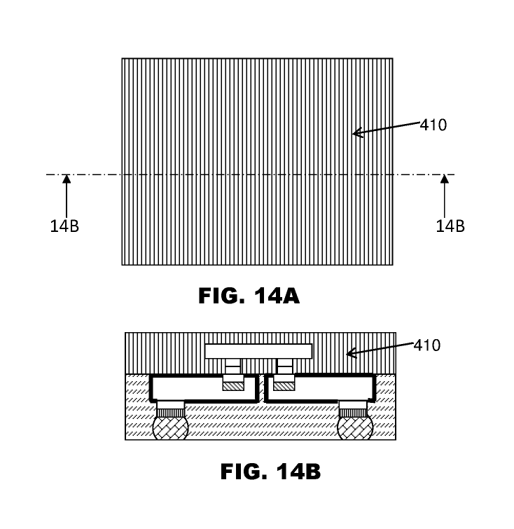

At step 230, the attached semiconductor die 390 is encapsulated by a second encapsulant 410 to form the final electronic device or semiconductor package, as shown in FIGS. 14A-14B. The second encapsulant 410 covers the bottom exposed surfaces 380 and the attached semiconductor die 390. The second encapsulant 410 allows the final electronic device to perform reliably in extreme operating temperature environments and to possess superior structural integrity.

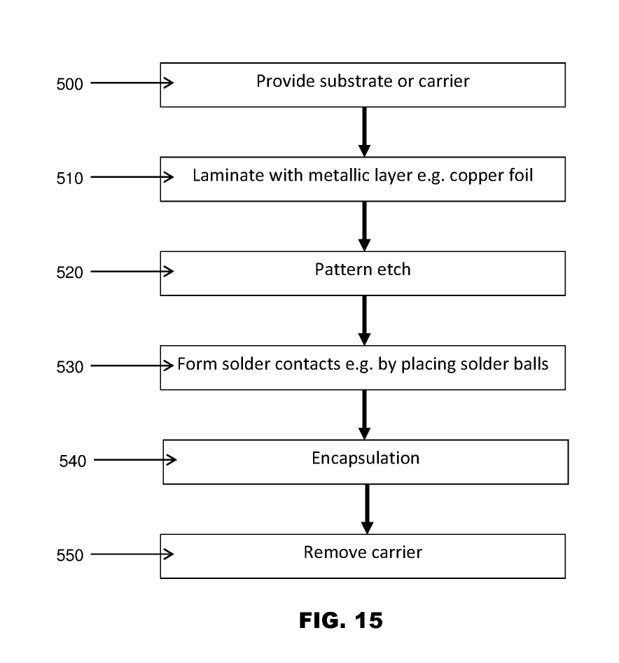

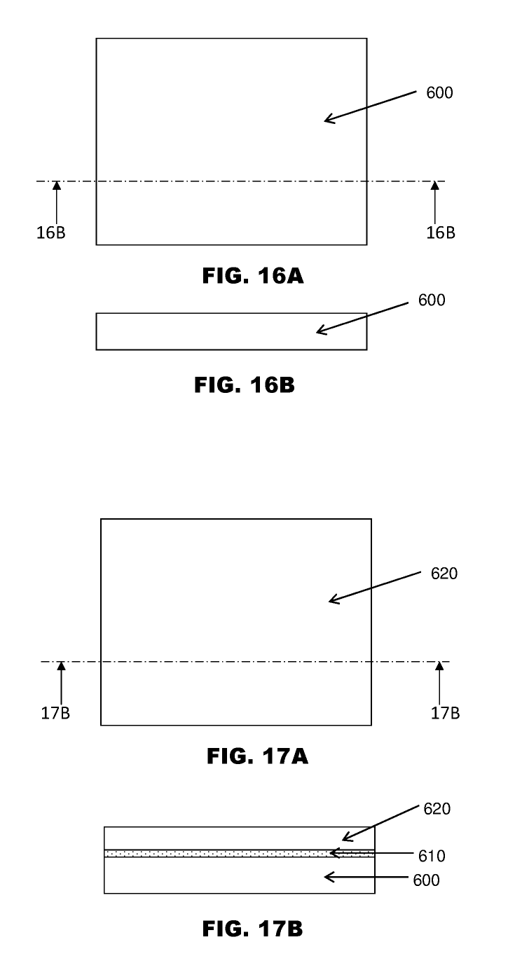

FIG. 15 is a flowchart showing the steps in another manufacturing process for forming a pre-molded substrate according to a second preferred embodiment of the invention, wherein FIGS. 16A through 21B illustrate plan and cross-sectional views of the pre-molded substrate at various stages of the manufacturing process of FIG. 15.

At step 500, a metallic substrate or carrier 600 is provided. A plan view of a first surface of the carrier 300 is shown in FIG. 16A, and FIG. 16B shows a cross-sectional view looking along line 16B-16B of FIG. 16A. The carrier 600 may act as a temporary carrier to be removed in a later processing step, as described below. The carrier 600 may also be, for example, PI tape, glass or a silicon substrate.

At step 510, a metallic layer 620 is formed onto the first surface of the carrier 600, as shown in FIGS. 17A-17B. The metallic layer 620 may be a copper foil laminated onto the carrier 600 by an adhesive 610. The thickness of the metallic layer 620 may vary widely, and is selected based on design specifications, such as the desired line width and spacing, of the final electronic device. The adhesive 610 used is selected to be compatible with downstream chemical and thermal processes.

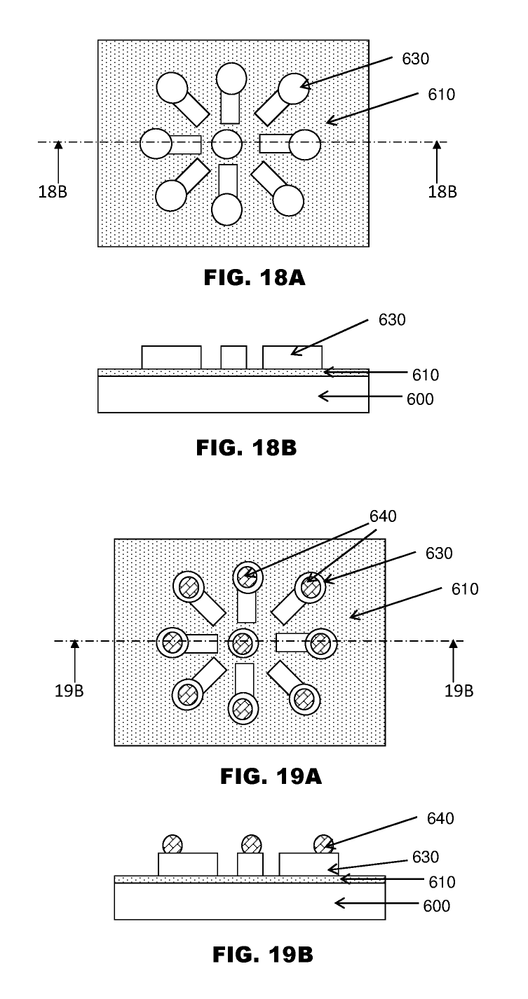

At step 520, a pattern etch is performed to form conductive circuits or metallic trace patterns 630, as shown in FIGS. 18A-18B. Cylindrical portions of the metallic trace patterns 630 may correspond to the positions of the BGA pads in the final electronic device. The metallic trace patterns 630 may comprise copper.

The metallic trace patterns 630 may be formed by applying an etching resist layer, such as a photoresist layer, onto the metallic layer 620, and masking, exposing, developing, and removing portions of the photoresist layer. Thereafter, areas of the metallic layer 620 located at removed portions of the photoresist layer may be removed. Such areas of the metallic layer 620 which are at removed portions of the photoresist layer may be removed by a dry etching method, a wet etching method such as chemical removal, or a combination of dry and wet etching methods. In addition, there are many other well-known etching processes and etchants in the art, and it is not intended that the present invention be limited to any particular etching process.

At step 530, a respective metallic contact, such as solder contact or solder ball 640, is formed on certain areas of each metallic trace pattern 630 or each cylindrical portion of the metallic trace patterns 630, as shown in FIGS. 19A-19B. The solder balls 640 may for instance be deposited by printing solder paste onto the metallic trace patterns 630, and thereafter reflowing and cleaning, or by placing solder balls 640 directly onto the metallic trace patterns 630.

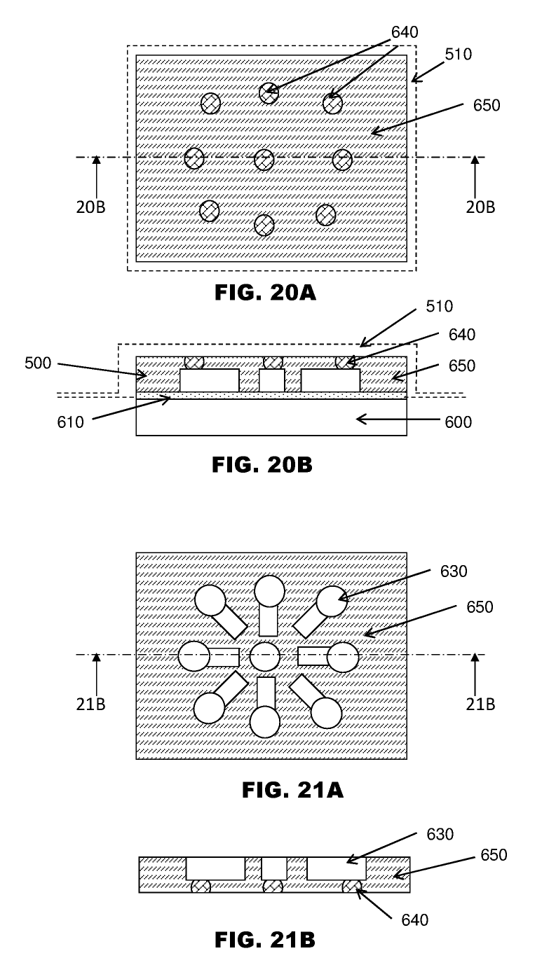

At step 540, the carrier 600 is encapsulated by an encapsulant 650, as shown in FIGS. 20A-20B. The encapsulant 650 covers the metallic trace patterns 630 and leaves top portions of the solder contacts 640 exposed. This encapsulation process may be similar to the first encapsulation process described with respect to step 180 and described above with reference to FIGS. 9A-9B.

At step 550, the carrier 600 and the adhesive 610 are removed to form the pre-molded substrate, as shown in FIGS. 21A-21B. The removal processes for the carrier 600 and the adhesive 610 may be similar to the removal processes described with respect to step 190 and described above with reference to FIGS. 10A-10B. Generally, the carrier 600 and the adhesive 610 is removed prior to mounting a semiconductor die onto the premolded substrate.

The pre-molded substrate shown in FIGS. 21A-21B has been flipped 180° such that the metallic trace patterns 630 are facing upwards and the exposed surfaces of the solder contacts 640 are facing downwards. Step 550 marks the end of the first assembly stage of the semiconductor packaging process.

A skilled person would appreciate that the pre-molded substrate of the first and second preferred embodiments of the present invention is a one-layer structure which utilizes simple and cost effective processing steps to manufacture. In addition, there is no need to grind any dielectric layer or to use solder resist, both of which may introduce impurities and complications into the manufacturing process. There is also no need to plate copper studs, which would be a clear advantage over conventional manufacturing processes for MIS and ETS.

Furthermore, the skilled person would appreciate that the first preferred embodiment would potentially be able to achieve a finer line width and spacing than the second preferred embodiment.

It should be recognized that the specifics of the various processes recited above are provided for illustrative purposes only, and that other processes and materials which provide equivalent results may be substituted therefor. Therefore, the spirit and scope of the appended claims should not be limited to the description of the embodiments contained herein.

1. A method of forming a premolded substrate for mounting a semiconductor die, the method comprising:
providing a carrier;
forming conductive circuits on the carrier;
forming a plurality of metallic contacts on the conductive circuits; and thereafter,
encapsulating the carrier by compressing a top portion of each metallic contact to crush and flatten the top portion of each metallic contact, and introducing a molding compound to surround the plurality of metallic contacts such that the flattened top surfaces of the plurality of metallic contacts are exposed on and flush with a top surface of the molding compound.

2. The method of claim 1, wherein the forming of the conductive circuits on the carrier comprises:
forming a layer of plating resist on the carrier;
removing portions of the layer of plating resist; and
filling a conductive material on the carrier at positions corresponding to the removed portions of the layer of plating resist, thereby forming the conductive circuits on the carrier.

3. The method of claim 2, wherein the conductive material comprises copper.

4. The method of claim 1, wherein the forming of the conductive circuits on the carrier comprises:
forming a layer of conductive material on the carrier;
forming a layer of etching resist on the layer of conductive material;
removing portions of the layer of etching resist; and
etching the layer of conductive material at positions corresponding to positions of the removed portions of the layer of etching resist.

5. The method of claim 4, wherein the layer of conductive material comprises copper.

6. The method of claim 1, wherein the encapsulating of the carrier is carried out while the carrier is clamped between top and bottom molds of a molding machine, and the compressing of the top portion of the metallic contacts is performed by a surface of the top or bottom mold.

7. The method of claim 1, wherein the plurality of metallic contacts comprises solder.

8. The method of claim 7, wherein the forming the plurality of metallic contacts on the conductive circuits comprises printing solder contacts onto the conductive circuits.

9. The method of claim 7, wherein each metallic contact is a solder ball which is placed onto the conductive circuits.

10. The method of claim 9, wherein the forming of the metallic contacts on the conductive circuits comprises:
depositing flux on the conductive circuits;
placing the solder balls on the flux and conductive circuits; and
reflowing the solder balls.

11. The method of claim 1, wherein the forming of the metallic contacts on the conductive circuits comprises:
forming metallic contact pads on the conductive circuits; and
forming the metallic contacts on the metallic contact pads.

12. The method of claim 1, wherein the forming of the conductive circuits on the carrier comprises:
forming a metallic layer on the carrier; and
forming the conductive circuits on the metallic layer.

13. The method of claim 1, further comprising:
forming electrical contacts on the carrier,
wherein the conductive circuits are connected to and at least partially surround the electrical contacts.

14. The method of claim 1, further comprising:
roughening exposed surfaces of the conductive circuits to promote adhesion between the exposed surfaces of the conductive circuits and the molding compound that is introduced in a subsequent step.

15. The method of claim 1, further comprising removing the carrier prior to mounting the semiconductor die onto the premolded substrate.

16. A premolded substrate for mounting a semiconductor die, the premolded substrate comprising:
conductive circuits;
a plurality of metallic contacts on the conductive circuits; and
a molding compound surrounding the plurality of metallic contacts and exposing a top surface of the metallic contacts;
wherein the top surfaces of the plurality of metallic contacts have been crushed and flattened to be flush with a top surface of the molding compound.
